(19) United States
(12) Patent Application Publication
(10) Pub. No.: US 2017/0062487 A1
(43) Pub. Date: Mar. 2, 2017

(54) Array Substrate and Manufacturing Method Thereof, Display Panel and Display Device

(71) Applicants: BOE Technology Group Co., Ltd., Beijing (CN); Hefei Xinsheng Optoelectronics Technology Co., Ltd, Hefei, Anhui (CN)

(72) Inventors: Zhixiang ZOU, Beijing (CN); Yinhu HUANG, Beijing (CN); Chengshao YANG, Beijing (CN); Botao SONG, Beijing (CN)

(21) Appl. No.: 15/022,036

(22) PCT Filed: Aug. 20, 2015
(86) PCT No.: PCT/CN2015/087592

§ 371 Date: Mar. 15, 2016

(30) Foreign Application Priority Data
Apr. 22, 2015 (CN) 201510195300.4

(51) Int. Cl. H01L 27/12; H01L 23/00; H01L 21/768

(52) U.S. Cl. CPC H01L 27/1248; H01L 27/1244; H01L 27/1262; H01L 21/76834; H01L 23/562

(57) ABSTRACT

The invention relates to the field of display design, and discloses an array substrate, a manufacturing method thereof, a display panel and a display device. The array substrate comprises a base substrate, and a peripheral gate line, a gate insulation layer, a peripheral data line and a protection layer which are formed on the base substrate in turn, wherein surface height of the protection layer corresponding to position where the peripheral gate line is located is higher than that of the protection layer corresponding to position where the peripheral data line is located. As such, when in contact with a peripheral wiring area of the array substrate, a foreign material is first in contact with the protection layer corresponding to position where the peripheral gate line is located, thereby reducing probability of crushing or scratching the peripheral data line by the foreign material, improving the stability of product performance.

### CROSS-REFERENCE TO RELATED APPLICATION

This application claims the priority of Chinese Patent Application No. 201510195300.4, filed on Apr. 22, 2015, the entire content of which is incorporated herein by reference.

### FIELD OF THE INVENTION

The present invention relates to the field of display design, and particularly relates to an array substrate and a manufacturing method thereof, a display panel and a display device.

### BACKGROUND OF THE INVENTION

In the design of peripheral wirings of an array substrate, peripheral gate lines and peripheral data lines are required to be alternatively arranged in a peripheral wiring area, in order to solve the problem of insufficient space. In the prior art, an outer surface (i.e., the surface far from a substrate) of a protection layer in the peripheral wiring area is flat, because thickness (200 nm to 400 nm) of the protection layer corresponding to positions where the peripheral data lines are located is smaller than a sum of thicknesses (a total of 600 nm to 800 nm) of an insulation layer and the protection layer corresponding to positions where the peripheral gate lines are located (i.e., compared with the peripheral data lines which are only protected by the protection layer, in addition to the protection of the protection layer, the peripheral gate lines are also protected by the insulation layer), compared with the peripheral gate lines, the peripheral data lines are more fragile and likely to be scratched or crushed by a foreign material, which leads to a problem of line defect, thereby influencing the stability of product performance.

### SUMMARY OF THE INVENTION

In view of the aforementioned problems, embodiments of the present invention provide an array substrate and a manufacturing method thereof, a display panel and a display device, which can reduce probability of crushing or scratching peripheral data lines by a foreign material, thereby improving the stability of the product performance.

According to embodiments of the present invention, an array substrate is provided, including: a base substrate, and a peripheral gate line, a gate insulation layer, a peripheral data line and a protection layer which are formed on the base substrate in turn, wherein a surface height of the protection layer corresponding to a position where the peripheral gate line is located is higher than that of the protection layer corresponding to a position where the peripheral data line is located.

Optionally, a groove is arranged at one part of the gate insulation layer corresponding to the peripheral data line, and the peripheral data line is formed in the groove, so as to enable at least one part of the peripheral data line in the height direction to fall into the groove.

Optionally, a depth of the groove in a direction perpendicular to the base substrate is 100 to 400 nm.

Optionally, the array substrate further includes a semiconductor layer which is located between the gate insulation layer and the protection layer, and overlapped with the peripheral gate line along the direction perpendicular to the base substrate.

Optionally, a thickness of the semiconductor layer in the direction perpendicular to the base substrate is 100 to 300 nm.

According to embodiments of the present invention, a display panel is further provided, including any one of the above array substrates.

According to embodiments of the present invention, a display device is further provided, including the above display panel.

According to embodiments of the present invention, a manufacturing method of an array substrate is further provided, including a step of:

forming a pattern of a peripheral gate line, a gate insulation layer, a pattern of a peripheral data line and a protection layer on the base substrate in turn, wherein a surface height of the protection layer corresponding to a position where the pattern of the peripheral gate line is located is higher than that of the protection layer corresponding to a position where the pattern of the peripheral data line is located.

Optionally, the manufacturing method specifically includes steps of:

forming a gate metal layer on the base substrate, and forming the pattern of the peripheral gate line;

forming a pattern of the gate insulation layer on the base substrate formed with the pattern of the peripheral gate line, the pattern of the gate insulation layer including a groove formed in a design area of the pattern of the peripheral data line;

forming a source-drain metal layer on the pattern of the gate insulation layer, and forming the pattern of the peripheral data line in the groove included in the pattern of the gate insulation layer, so as to enable at least one part of the pattern of the peripheral data line in the height direction to fall into the groove; and

forming the protection layer on the base substrate formed with the pattern of the peripheral data line and the pattern of the gate insulation layer.

Optionally, a depth of the groove in a direction perpendicular to the base substrate is 100 to 400 nm.

Optionally, the manufacturing method specifically includes steps of:

forming a gate metal layer on the base substrate, and forming the pattern of the peripheral gate line;

forming the gate insulation layer on the base substrate formed with the pattern of the peripheral gate line;

forming a pattern of the semiconductor layer on the gate insulation layer, wherein the pattern of the semiconductor layer is arranged at one part which is overlapped with the pattern of the peripheral gate line along a direction perpendicular to the base substrate;

forming a source-drain metal layer on the gate insulation layer, and forming the pattern of the peripheral data line; and

forming the protection layer on the base substrate formed with the pattern of the peripheral data line, the gate insulation layer and the pattern of the semiconductor layer.

Optionally, a thickness of the semiconductor layer in the direction perpendicular to the base substrate is 100 to 300 nm.

Optionally, the manufacturing method specifically includes steps of:

forming a gate metal layer on the base substrate, and forming the pattern of the peripheral gate line;

forming a pattern of the gate insulation layer on the base substrate formed with the pattern of the peripheral gate line, the pattern of the gate insulation layer including a groove formed in a design area of the pattern of the peripheral data line;

forming a pattern of a semiconductor layer on the pattern of the gate insulation layer, wherein the pattern of the semiconductor layer is arranged at one part which is overlapped with the pattern of the peripheral gate line along a direction perpendicular to the base substrate;

forming a source-drain metal layer on the pattern of the gate insulation layer, and forming the pattern of the peripheral data line in the groove included in the pattern of the gate insulation layer, so as to enable at least one part of the pattern of the peripheral data line in the height direction to fall into the groove; and

forming the protection layer on the base substrate formed with the pattern of the peripheral data line, the pattern of the gate insulation layer and the pattern of the semiconductor layer.

Optionally, a thickness of the semiconductor layer in the direction perpendicular to the base substrate is 100 to 300 nm.

Optionally, a depth of the groove in the direction perpendicular to the base substrate is 100 to 400 nm.

In the array substrate and the manufacturing method thereof, the display panel and the display device provided according to embodiments of the present invention, because the surface height of the protection layer corresponding to the position where the peripheral gate line is located is higher than that of the protection layer corresponding to the position where the peripheral data line is located, when in contact with the peripheral wiring area of the array substrate, a foreign material is first in contact with the protection layer corresponding to the position where the peripheral gate line is located, thereby reducing probability of contact between the foreign material and the protection layer corresponding to the position where the peripheral data line is located, to reduce probability of crushing or scratching the peripheral data line by the foreign material, and improve the stability of the product performance.

### BRIEF DESCRIPTION OF THE DRAWINGS

FIG. 1 is a structural diagram of an array substrate provided by embodiments of the present invention;

FIG. 2 is another structural diagram of an array substrate provided by embodiments of the present invention; and

FIG. 3 is still another structural diagram of an array substrate provided by embodiments of the present invention.

### DESCRIPTION OF THE PREFERRED EMBODIMENT

The technical solutions in embodiments of the present invention will be described clearly and completely as below with reference to the accompanying drawings in embodiments of the present invention, obviously, the described embodiments are not all the embodiments, but only part of embodiments of the present invention. According to the embodiments of the present invention, all other embodiments obtained by those skilled in the art without creative effort fall into the protection scope of the present invention.

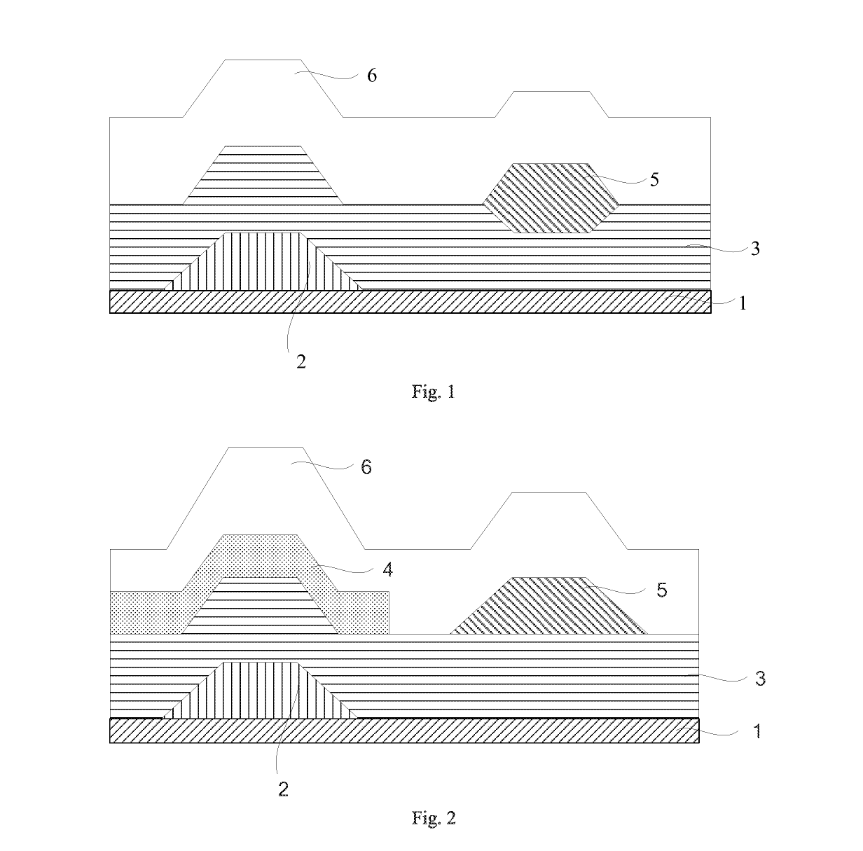

According to embodiments of the present invention, an array substrate, a display panel including the array substrate, and a display device including the display panel are provided. As shown in FIG. 1 to FIG. 3, the array substrate includes a base substrate 1, and a peripheral gate line 2, a gate insulation layer 3, a peripheral data line 5 and a protection layer 6 which are formed on the base substrate 1 in turn, wherein a surface height of the protection layer 6 corresponding to a position where the peripheral gate line 2 is located is higher than that of the protection layer 6 corresponding to a position where the peripheral data line 5 is located. Because the surface height of the protection layer 6 corresponding to the position where the peripheral gate line 2 is located is higher than that of the protection layer 6 corresponding to the position where the peripheral data line 5 is located, when in contact with the peripheral wiring area of the array substrate, a foreign material is first in contact with the protection layer 6 corresponding to the position where the peripheral gate line 2 is located, thereby reducing probability of contact between the foreign material and the protection layer 6 corresponding to the position where the peripheral data line 5 is located, to reduce probability of crushing or scratching the peripheral data line 5 by the foreign material, and improve the stability of the product performance. Furthermore, the stabilities of the product performances of the display panel including the array substrate and the display device including the display panel are improved.

According to embodiments of the present invention, a manufacturing method of an array substrate is further provided, including a step of: forming a pattern of a peripheral gate line, a gate insulation layer, a pattern of a peripheral data line and a protection layer on a base substrate in turn, wherein, a surface height of the protection layer corresponding to a position where the pattern of the peripheral gate line is located is higher than that of the protection layer corresponding to a position where the pattern of the peripheral data line is located.

Specifically, the array substrate, through the following specific structures, may achieve that the surface height of the protection layer corresponding to the position where the pattern of the peripheral gate line is located is higher than that of the protection layer corresponding to the position where the pattern of the peripheral data line is located.

First mode: as shown in FIG. 1, the array substrate provided by the embodiments of the present invention includes a base substrate 1, and a peripheral gate line 2, a gate insulation layer 3, a peripheral data line 5 and a protection layer 6 which are formed on the base substrate 1 in turn. Wherein, a groove is arranged at one part of the gate insulation layer 3 corresponding to the peripheral data line 5, and the peripheral data line 5 is formed in the groove, so as to enable at least one part of the peripheral data line 5 in the height direction to fall into the groove.

In the array substrate, because at least one part of the peripheral data line 5 in the height direction is fallen into the groove, compared with the prior art, during formation of the protection layer 6, the surface height of the protection layer 6 corresponding to the position where the peripheral data line 5 is located may be reduced, and yet the surface height of the protection layer 6 corresponding to the position where the peripheral gate line 2 is located is not changed, thereby enabling the surface height of the protection layer 6 corresponding to the position where the peripheral gate line 2 is located to be higher than that of the protection layer 6 corresponding to the position where the peripheral data line 5 is located.

Optionally, a depth of the groove in the direction perpendicular to the base substrate 1 is 100 to 400 nm, such as 100 nm, 150 nm, 200 nm, 250 nm, 300 nm, 350 nm, and 400 nm.

Correspondingly, the array substrate provided in the first mode may be manufactured by following manufacturing method, which specifically includes steps of:

forming a gate metal layer on the base substrate 1 through a single patterning process, and forming a pattern of the peripheral gate line 2;

forming a pattern of the gate insulation layer 3 on the base substrate 1 formed with the pattern of the peripheral gate line 2 through a halftone mask process, wherein the pattern of the gate insulation layer 3 includes a groove formed in a design area of the pattern of the peripheral data line 5;

forming a source-drain metal layer on the pattern of the gate insulation layer 3 through a single patterning process, and forming the pattern of the peripheral data line 5 in the groove included in the pattern of the gate insulation layer 3, so as to enable at least one part of the pattern of the peripheral data line 5 in the height direction to fall into the groove; and

forming the protection layer 6 on the base substrate 1 formed with the pattern of the peripheral data line 5 and the pattern of the gate insulation layer 3.

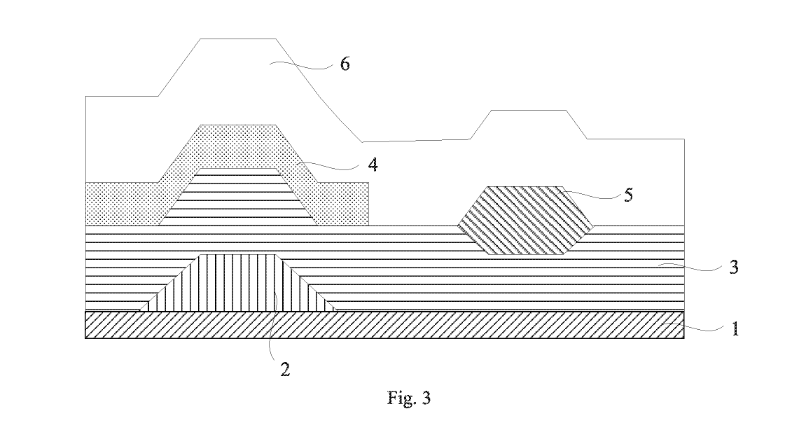

Second mode: as shown in FIG. 2, the array substrate provided by the embodiments of the present invention includes a substrate 1, and a peripheral gate line 2, a gate insulation layer 3, a semiconductor layer 4, a peripheral data line 5 and a protection layer 6 which are formed on the base substrate 1 in turn. Wherein, the semiconductor layer 4 is located between the gate insulation layer 3 and the protection layer 6, and overlapped with the peripheral gate line 2 along the direction perpendicular to the base substrate 1.

Because the semiconductor layer 4, located between the gate insulation layer 3 and the protection layer 6, is overlapped with the peripheral gate line 2 along the direction perpendicular to the base substrate 1, compared with the prior art, the surface height of the protection layer 6 corresponding to the position where the peripheral gate line 2 is located may be increased, and yet the surface height of the protection layer 6 corresponding to the position where the peripheral data line 5 is located is not changed, thereby enabling the surface height of the protection layer 6 corresponding to the position where the peripheral gate line 2 is located to be higher than that of the protection layer 6 corresponding to the position where the peripheral data line 5 is located.

Optionally, a thickness of the semiconductor layer 4 in the direction perpendicular to the base substrate 1 is 100 to 300 nm, such as 100 nm, 130 nm, 150 nm, 200 nm, 230 nm, 250 nm, and 300 nm.

Correspondingly, the array substrate provided in the second mode may be manufactured by the following manufacturing method, and the manufacturing method specifically includes steps of:

forming a gate metal layer on the base substrate 1 through a single patterning process, and forming a pattern of the peripheral gate line 2;

forming a gate insulation layer 3 on the base substrate 1 formed with the pattern of the peripheral gate line 2;

forming a pattern of the semiconductor layer 4 on the gate insulation layer 3, wherein the pattern of the semiconductor layer 4 is arranged at one part which is overlapped with the peripheral gate line 2 along the direction perpendicular to the base substrate 1;

forming a source-drain metal layer on the gate insulation layer 3, and forming a pattern of the peripheral data line 5; and

forming the protection layer 6 on the base substrate 1 formed with the pattern of the peripheral data line 5, the gate insulation layer 3 and the pattern of the semiconductor layer 4.

Third mode: As shown in FIG. 3, the array substrate provided by the embodiments of the present invention includes a base substrate 1, and a peripheral gate line 2, a gate insulation layer 3, a semiconductor layer 4, a peripheral data line 5 and a protection layer 6 which are formed on the base substrate 1 in turn. Wherein, a groove is arranged at one part of the gate insulation layer 3 corresponding to the peripheral data line 5, and the peripheral data line 5 is formed in the groove, so as to enable at least one part of the peripheral data line 5 in the height direction to fall into the groove; the semiconductor layer 4 is located between the gate insulation layer 3 and the protection layer 6, and overlapped with the peripheral gate line 2 along the direction perpendicular to the base substrate 1.

In the array substrate, because at least one part of the peripheral data line 5 in the height direction is fallen into the groove, compared with the prior art, during formation of the protection layer 6, the surface height of the protection layer 6 corresponding to the position where the peripheral data line 5 is located may be reduced; meanwhile, because the semiconductor layer 4, located between the gate insulation layer 3 and the protection layer 6, is overlapped with the peripheral gate line 2 along the direction perpendicular to the base substrate 1, compared with the prior art, the surface height of the protection layer 6 corresponding to the position where the peripheral gate line 2 is located may be increased. Hence, the surface height of the protection layer 6 corresponding to the position where the peripheral gate line 2 is located is higher than that of the protection layer 6 corresponding to the position where the peripheral data line 5 is located.

Optionally, the depth of the groove in the direction perpendicular to the base substrate is 100 to 400 nm, such as 100 nm, 150 nm, 200 nm, 250 nm, 300 nm, 350 nm, and 400 nm.

Optionally, a thickness of the semiconductor layer 4 in the direction perpendicular to the base substrate 1 is 100 to 300 nm, such as 100 nm, 130 nm, 150 nm, 200 nm, 230 nm, 250 nm, and 300 nm.

Correspondingly, the array substrate provided in the third mode may be manufactured by following manufacturing method, and the manufacturing method specifically includes steps of:

forming a gate metal layer on the base substrate 1 through a single patterning process, and forming a pattern of the peripheral gate line 2;

forming a pattern of the gate insulation layer 3 on the base substrate 1 formed with the pattern of the peripheral gate line 2, wherein the pattern of the gate insulation layer 3 includes a groove formed in a design area of the pattern of the peripheral data line 5;

forming a pattern of the semiconductor layer 4 on the pattern of the gate insulation layer 3, wherein the pattern of the semiconductor layer 4 is arranged at one part which is overlapped with the peripheral gate line 2 along the direction perpendicular to the base substrate 1;

forming a source-drain metal layer on the pattern of the gate insulation layer 3 through a single patterning process, and forming a pattern of the peripheral data line 5 in the groove included in the pattern of the gate insulation layer 3, so as to enable at least one part of the pattern of the peripheral data line 5 in the height direction to fall into the groove; and

forming the protection layer 6 on the base substrate 1 formed with the pattern of the peripheral data line 5, the pattern of the gate insulation layer 3 and the pattern of the semiconductor layer 4.

Certainly, the above array substrates may be embodied through other structures, as long as the surface height of the protection layer corresponding to the position where the peripheral gate line is located is higher than that of the protection layer corresponding to the position where the peripheral data line is located, probability of crushing or scratching the peripheral data line by the foreign material may be reduced, thereby improving the stability of the product performance.

Apparently, a person of ordinary skill in the art may make various improvements and variations on the embodiments of the present invention without departing from the spirit and scope of the present invention. In this way, if those improvements and variations of the present invention fall into the scope of the claims and equivalent technologies of the present invention, the present invention is also intended to include those improvements and variations therein.

1-15. (canceled)

16. An array substrate, comprising: a base substrate, and a peripheral gate line, a gate insulation layer, a peripheral data line and a protection layer which are formed on the base substrate in turn, wherein a surface height of the protection layer corresponding to a position where the peripheral gate line is located is higher than that of the protection layer corresponding to a position where the peripheral data line is located.

17. The array substrate according to claim 16, wherein a groove is arranged at one part of the gate insulation layer corresponding to the peripheral data line, and the peripheral data line is formed in the groove, so as to enable at least one part of the peripheral data line in the height direction to fall into the groove.

18. The array substrate according to claim 17, wherein a depth of the groove in a direction perpendicular to the base substrate is 100 to 400 nm.

19. The array substrate according to claim 16, wherein the array substrate further comprises a semiconductor layer which is located between the gate insulation layer and the protection layer, and overlapped with the peripheral gate line along a direction perpendicular to the base substrate.

20. The array substrate according to claim 17, wherein the array substrate further comprises a semiconductor layer which is located between the gate insulation layer and the protection layer, and overlapped with the peripheral gate line along a direction perpendicular to the base substrate.

21. The array substrate according to claim 19, wherein a thickness of the semiconductor layer in the direction perpendicular to the base substrate is 100 to 300 nm.

22. The array substrate according to claim 20, wherein a thickness of the semiconductor layer in the direction perpendicular to the base substrate is 100 to 300 nm.

23. A display panel, comprising an array substrate, which comprises: a base substrate, and a peripheral gate line, a gate insulation layer, a peripheral data line and a protection layer which are formed on the base substrate in turn, wherein a surface height of the protection layer corresponding to a position where the peripheral gate line is located is higher than that of the protection layer corresponding to a position where the peripheral data line is located.

24. The display panel according to claim 23, wherein a groove is arranged at one part of the gate insulation layer corresponding to the peripheral data line, and the peripheral data line is formed in the groove, so as to enable at least one part of the peripheral data line in the height direction to fall into the groove.

25. The display panel according to claim 23, wherein the array substrate further comprises a semiconductor layer which is located between the gate insulation layer and the protection layer, and overlapped with the peripheral gate line along a direction perpendicular to the base substrate.

26. A display device, comprising the display panel according to claim 23.

27. A manufacturing method of an array substrate, comprising a step of:
forming a pattern of a peripheral gate line, a gate insulation layer, a pattern of a peripheral data line and a protection layer on a base substrate in turn, wherein a surface height of the protection layer corresponding to a position where the pattern of the peripheral gate line is located is higher than that of the protection layer corresponding to a position where the pattern of the peripheral data line is located.

28. The manufacturing method according to claim 27, wherein the step of forming the pattern of the peripheral gate line, the gate insulation layer, the pattern of the peripheral data line and the protection layer on the base substrate in turn comprises steps of:
forming a gate metal layer on the base substrate, and forming the pattern of the peripheral gate line;
forming a pattern of the gate insulation layer on the base substrate formed with the pattern of the peripheral gate line, the pattern of the gate insulation layer comprising a groove formed in a design area of the pattern of the peripheral data line;
forming a source-drain metal layer on the pattern of the gate insulation layer, and forming the pattern of the peripheral data line in the groove included in the pattern of the gate insulation layer, so as to enable at least one part of the pattern of the peripheral data line in the height direction to fall into the groove; and
forming the protection layer on the base substrate formed with the pattern of the peripheral data line and the pattern of the gate insulation layer.

29. The manufacturing method according to claim 28, wherein a depth of the groove in a direction perpendicular to the base substrate is 100 to 400 nm.

30. The manufacturing method according to claim 27, wherein the step of forming the pattern of the peripheral gate line, the gate insulation layer, the pattern of the peripheral data line and the protection layer on the base substrate in turn comprises steps of:
forming a gate metal layer on the base substrate, and forming the pattern of the peripheral gate line;
forming the gate insulation layer on the base substrate formed with the pattern of the peripheral gate line;
forming a pattern of the semiconductor layer on the gate insulation layer, wherein the pattern of the semiconductor layer is arranged at one part which is overlapped with the pattern of the peripheral gate line along a direction perpendicular to the base substrate;
forming a source-drain metal layer on the gate insulation layer, and forming the pattern of the peripheral data line; and
forming the protection layer on the base substrate formed with the pattern of the peripheral data line, the gate insulation layer and the pattern of the semiconductor layer.

31. The manufacturing method according to claim 30, wherein a thickness of the semiconductor layer in the direction perpendicular to the base substrate is 100 to 300 nm.

32. The manufacturing method according to claim 27, wherein the step of forming the pattern of the peripheral gate line, the gate insulation layer, the pattern of the peripheral data line and the protection layer on the base substrate in turn comprises steps of:
forming a gate metal layer on the base substrate, and forming the pattern of the peripheral gate line;
forming a pattern of the gate insulation layer on the base substrate formed with the pattern of the peripheral gate line, the pattern of the gate insulation layer comprising a groove formed in a design area of the pattern of the peripheral data line;
forming a pattern of a semiconductor layer on the pattern of the gate insulation layer, wherein the pattern of the semiconductor layer is arranged at one part which is overlapped with the pattern of peripheral gate line along a direction perpendicular to the base substrate;
forming a source-drain metal layer on the pattern of the gate insulation layer, and forming the pattern of the peripheral data line in the groove included in the pattern of the gate insulation layer, so as to enable at least one part of the pattern of the peripheral data line in the height direction to fall into the groove; and
forming the protection layer on the base substrate formed with the pattern of the peripheral data line, the pattern of the gate insulation layer and the pattern of the semiconductor layer.

33. The manufacturing method according to claim 32, wherein a thickness of the semiconductor layer in the direction perpendicular to the base substrate is 100 to 300 nm.

34. The manufacturing method according to claim 32, wherein a depth of the groove in the direction perpendicular to the base substrate is 100 to 400 nm.

35. The manufacturing method according to claim 33, wherein a depth of the groove in the direction perpendicular to the base substrate is 100 to 400 nm.
